(19) United States
(12) Patent Application Publication
(10) Pub. No.: US 2002/0163348 A1
(43) Pub. Date: Nov. 7, 2002

(54) Scanning laser beam electrical circuit inspection system

(75) Inventors: Eyal Harel, Tel Aviv (IL); Yehoshua Dollberg, Raanana (IL); Ben-Zion Lavi, Rehovot (IL)

Correspondence Address: Ladas & Parry, 26 West 61st Street, New York, NY, 10023, US

(73) Assignee: ORBOTECH LTD.

(21) Appl. No.: 09/846,999

(22) Filed: May 1, 2001

(51) Int. Cl. G01R 31/302

(52) U.S. Cl. 324/752

(57) ABSTRACT

An automated optical inspection system is operative to convey an electrical circuit to be inspected in a first direction. While the electrical circuit is being conveyed a laser beam scanner scans a laser beam in second direction, generally perpendicular to the first direction, and a fluorescence detector detects fluorescence produced by impingement of the laser beam on portions of the electrical circuit. The fluorescence detector receives fluorescence sequentially from portions of the electrical circuit illuminated by the laser beam as a result of both conveying of the electrical circuit and scanning of the laser beam in the second direction.

### FIELD OF THE INVENTION

The present invention relates to automated optical inspection of electrical circuits.

### BACKGROUND OF THE INVENTION

It is known to employ automated optical inspection (“AOI”) systems to optically inspect patterns forming parts of electrical circuits. Some conventional AOI systems, such as the SK-75™ and Inspire 9060™ AOI systems, available from Orbotech Ltd. of Israel, employ focused generally white light to illuminate electrical circuits being inspected. Other AOI systems, such as the V-300™ AOI system, available from Orbotech Ltd. of Israel, employ a scanning laser beam to illuminate electrical circuits being inspected.

### SUMMARY OF THE INVENTION

The present invention seeks to provide improved systems and methodologies for automated optical inspection of electrical circuit patterns.

In accordance a broad aspect of the invention an automated optical inspection system is provided to convey an electrical circuit to be inspected in a first direction. While the electrical circuit is being conveyed a laser beam scanner scans a laser beam in second direction, generally perpendicular to the first direction, and a fluorescence detector detects fluorescence produced by impingement of the laser beam on portions of the electrical circuit. The fluorescence detector receives fluorescence sequentially from portions of the electrical circuit illuminated by said laser beam as a result of both conveying of the electrical circuit and scanning of said laser beam in the second direction.

In accordance with another broad aspect of the invention there is provided an automated optical inspection having a conveying subsystem conveying an electrical circuit to be inspected in a first direction; a laser scanner scanning a laser beam in a single pass across said entire electrical circuit in a second direction generally perpendicular the first direction; and a fluorescence detector detecting fluorescence produced by impingement of the laser beam on portions of said electrical circuit

In accordance with still another broad aspect of the invention, an electrical circuit inspection system is operative to scan a laser beam in at least one second direction which generally perpendicular a direction in which an electrical circuit under inspection is being conveyed. A fluorescence detector detects fluorescence produced by impingement of the scanned laser beam on the electrical circuit.

In accordance with still another broad aspect of the invention, a scanning laser inspection system is provided with a scanning laser generated by a laser beam generator chosen from the group consisting of diode lasers and frequency transformed optically pumped semiconductor lasers. A fluorescence detector detects fluorescence produced by impingement of the laser beam on the electrical circuit.

In accordance with still another broad aspect of the invention an inspection facility is provided with scanning laser inspection systems having one or more of several laser beam generators, each generating laser beams with a different spectral characteristic. A laser beam generator, or an inspection system, is selected as a function of fluorescent response between a laser beam emitted by a laser beam generator and a substrate portion of an electrical circuit to be inspected.

### BRIEF DESCRIPTION OF THE DRAWINGS

The present invention will be understood and appreciated more fully from the following detailed description, taken in conjunction with the drawings in which:

FIG. 1 is a simplified generally pictorial illustration of a system for automated optical inspection of electrical circuits; and

FIG. 2 is a simplified illustration of a portion of the system of FIG. 1.

### DETAILED DESCRIPTION OF A PREFERRED EMBODIMENT

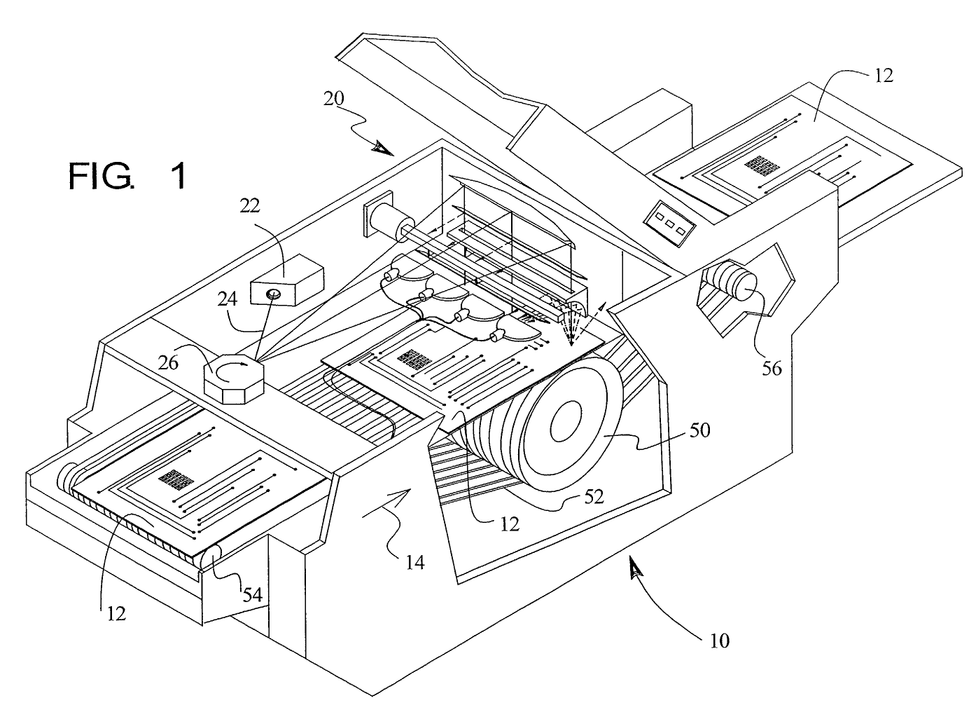

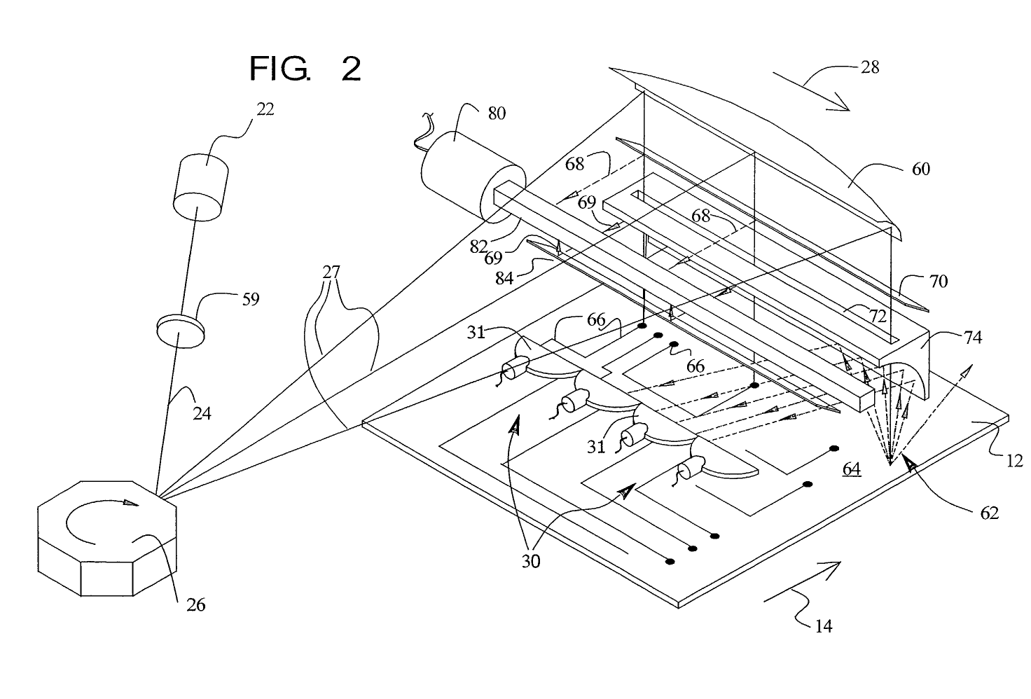

Reference is now made to FIGS. 1 and 2 which illustrate an inspection system for electrical circuits including a conveying subsystem, designated generally by reference numeral 10, which is operative for conveying an electrical circuit board 12 to be inspected generally in a direction indicated by an arrow 14.

An inspection subsystem, designated generally by reference numeral 20 is operative for performing optical inspection of electrical circuitry on electrical circuit board 12 as the board 12 is being conveyed in the direction indicated by arrow 14. Inspection subsystem preferably includes an illumination path defined by a scanned laser beam impinging on an electrical circuit board 12 to be inspected, and a collection path preferably defined by the path of fluorescent emission from the electrical circuit board 12 to be inspected, caused by impingement of the illuminating laser beam thereon, to one or more fluorescent light detectors. Optionally the collection path may be further defined by the path of light from the scanned beam reflected off of the electrical circuit board 12 to be inspected to a reflective light detector.

In accordance with a preferred embodiment of the present invention, the inspection subsystem 20 includes a laser beam generator 22, generating a laser beam 24 which impinges on a laser beam scanner 26, preferably a rotating polygon, but alternatively any other suitable scanning device. The laser beam scanner 26 scans the laser beam 24 in a direction lying along an axis, indicated by an arrow 28 (FIG. 2), and preferably across substantially the entire width of electrical circuit board 12. Downstream of scanner 26 laser beam 24 is referred to as scanned laser beam 27. In the embodiment shown in FIGS. 1 and 2 the location of scanned laser beam 27 on the surface of electrical circuit board 12 is a function of the angular position of rotating polygon mirror forming scanner 26.

It is noted that the axis along which lies arrow 28 is preferably generally perpendicular to the first direction indicated by arrow 14. Preferably laser beam scanner 26 is operative to scan scanned laser beam 27 in a single pass across the entire width of electrical circuit board 12, in a direction which is at least generally perpendicular to the direction indicated by arrow 14. Typically, the width of circuit board 12 ranges between 18″ and 24″, and scanning in a single pass facilitates inspection of circuit board 12 in a single swath, preferably while being continuously transported in the direction of arrow 14.

In accordance with a preferred embodiment of the present invention, there is provided at least one fluorescence detector 30, and preferably several fluorescence detectors 30 arranged side-by-side, for detecting fluorescence produced by impingement of the scanned laser beam on portions of the electrical circuit formed on circuit board 12. Fluorescent detectors 30 preferably are photo-multiplier tubes, avalanche diodes or other suitable detectors sufficiently sensitive to detect very low intensity light characteristic of laser stimulated fluorescent emission by typical electrical circuit board substrates. Preferably, fluorescent detectors are provided with a light guide element 31 enabling detection of fluorescent emission over a finite area.

Preferably, the at least one fluorescence detector 30 receives fluorescence sequentially from portions of the electrical circuit illuminated by the scanned laser beam as a result of both conveying of the electrical circuit board 12 in the direction indicated by arrow 14 and scanning of the laser beam in second direction 28. Preferably, the respective outputs of the at least one fluorescence detector 30 are supplied to circuitry (not shown) which correlates between the intensity of the fluorescent output and a position of scanned laser beam 27, as it is scanned, on the surface of electrical circuit board 12. It is appreciated that because fluorescent emission typically is multidirectional, the impingement of scanned laser beam 27 at some locations along electrical circuit board 12 may produce a fluorescent emission impinging on more than a single detector 30. Therefore, for such locations of scanned laser beam 27, the outputs of adjacent detectors 30 may be summed.

The position of scanned laser beam 27 on electrical circuit board 12 is derived from determination of a location of scanned beam 27 as it is scanned along axis 28 and a location of board 12 in the direction indicated by arrow 14 as it is conveyed past subsystem 20, to indicate a portion of board 12 being illuminated.

As shown in FIG. 1, the conveying subsystem 10 preferably comprises a rotating drum 50 which drives a plurality of bands 52, which are tensioned over the drum 50, and a pair of rollers 54 and 56, disposed at respective opposite ends of a generally linear, preferably horizontal travel path. The electrical circuit boards 12 travel along the travel path, supported by bands 52.

The illumination path of inspection subsystem 20 between laser beam generator 22 and the electrical circuit board 12, shown in greater detail in FIG. 2, preferably is generally telecentric and preferably includes pre-scanning optics comprising one or more lenses 59 upstream of scanner 26 operative to focus beam 24 to a suitable spot, and scanning optics including an f-θ optical element 60. F-θ optical element 60 preferably comprises a mirror having an aspherical and cylindrically curved surface designed to achieve desired telecentric, field flattening and f-θ properties. General design principles of wide format scanning mirrors are described in K. Klose, “Application of Additional Mirrors for Rectilinear Laser Scanning of Wide Formats”, Applied Optics, Vol. 17, NO. 2 (1978), pp. 203-210, the disclosure of which is incorporated by reference. A mirror based flat field imaging subsystem presently integrated into computer to plate platesetting systems, the design principles of which may be adapted for use in inspection subsystem 20, is available from Axsys Technologies, Inc. of Connecticut, U.S.A.

Alternatively, optical element 60 may be formed of both parabolic and hyperbolic optical surfaces, preferably constructed and operative in accordance with teachings contained in one or all of the following publications: van Amstel, Principles of the Ideal Scanner Model, presented at the EOS/SPIE Symposium on Optical Systems Design and Production, May 25-28, 1999; and van Amstel et. al., Banana Technology, presented at the EOS/SPIE Symposium on Optical Systems Design and Production, May 25-28, 1999, the disclosures of which are incorporated by reference. Still alternatively, the f-θ optical element 60 may be any suitable lens or reflective element, or a combination of lenses and reflective elements.

Preferably laser beam generator 22 comprises a He:Cd gas laser, such as a He:Cd laser available from Melles Griot of Carlsbad, Calif. or from Kimmon of Japan, emitting beam 24 generally in the blue spectrum, at about 440 nM. Other suitable laser beam generators, producing a fluorescent emission when impinging upon substrate materials used in printed circuit board manufacture, may be used. Such other suitable laser beam generators, include, for example, solid state and diode lasers, such as a gallium:nitride diode laser emitting a laser beam at about 405 nM, and a frequency doubled optically pumped semiconductor laser, as is available from Coherent of Santa Clara, Calif., emitting a laser beam at about 460 nM.

Where scanned beam 27 impinges on a substrate portion 64 of circuit board 12, a multi-directional fluorescent emission is produced, indicated generally by reference numeral 62. Where scanned beam 27 impinges on conductive portions 66 of circuit board 12, it is reflected as indicated generally by reference numeral 68.

It is appreciated that substrates employed in electrical circuit 12 may be formed of different materials, and that each of the different materials exhibits a characteristic fluorescent response when impinged upon by laser radiation at different wavelengths. Thus, in accordance with a preferred embodiment of the invention, a circuit board inspection facility preferably is provided with several inspection systems, each of which employs a laser beam generator 22 emitting a beam 24 at a different characteristic wavelength. In such a facility, circuit boards 12 are inspected using an inspection system that employs a laser beam generator 22 emitting a laser beam 24 that produces a relatively high efficiency response, namely fluorescent emission, for the substrate material forming such a board.

Alternatively, an inspection subsystem (not shown) is provided with optics that preferably are chromatically optimized for use with beams at two or more characteristic wavelengths. At least two laser beam generators, or optionally a tunable laser, are provided to output beams in the wavelength ranges for which the optics are optimized. The at least two laser beam generators may be interchangeable. Alternatively two or more laser beam generators are simultaneously mounted in an inspection subsystem 20. In such an arrangement, a beam combiner or switch (not shown) is employed to provide a laser beam from the laser beam generator of choice so as to achieve an optimal fluorescent response for the substrate material in the circuit board 12 under inspection.

Returning to FIG. 2, along an illumination path of inspection subsystem 20, the scanned beam 27 preferably is scanned by the polygon mirror of scanner 26 onto f-θ optical element 60. From f-θ optical element 60, scanned beam 27 travels via a beam splitter 70 and passes through a slit 72 in an elliptical cylindrical mirror 74, to impinge on the electrical circuit board 12 at a location which is generally at a first focus of elliptical cylindrical mirror 74.

In accordance with a preferred embodiment of the invention, the at least one fluorescence detector 30 is provided near, but not at, a second focus of elliptical cylindrical mirror 74. It is appreciated that fluorescent emission is in a different spectrum, typically yellow, compared to the scanning beam 27, which preferably is blue. Fluorescent emission 62 occurring where scanned beam 27 impinges on electrical circuit board 12 is collected by mirror 74 and directed to at least one of fluorescence detectors 30. Preferably a stop (not shown) is provided upstream of detectors 30 to define a field of view for the fluorescent emission 62 impinging on detectors 30. It is appreciated that at various locations along the axis indicated by arrow 28, fluorescent emission 62, which typically is multidirectional, may impinge on more than one fluorescence detector 30. At such locations the intensities of the outputs of adjacent detectors preferably are summed to provide an indication of the total fluorescent emission at those points of impingement on substrate 64.

In accordance with a preferred embodiment of the present invention, there also is provided at least one reflectance detector 80 coupled via a beam splitter 84 and a light guide 82 preferably located near, but not at, a virtual location of the second focus of elliptical mirror 74.

Preferably, at least some light reflected from conductor portions 66 of the electrical circuit board 12, indicated by reference numeral 68, passes through slit 72 in elliptical mirror 74 and is reflected by beam splitter 70 onto light guide 82. Additionally, inasmuch as some portions of light reflected from conductor portions 66 of the electrical circuit board 12 do not pass through slit 72, indicated by reference numeral 69, they are collected by elliptical mirror 74, reflected toward beam splitter 84 and thence reflected to light guide 82.

As seen in FIG. 2, beam splitter 84 is located in the path of both fluorescent emission 62 and reflected light portions 69. It is appreciated that beam splitter 84 preferably is configured to at least partially reflect light portions 69 that are reflected by conductor portions 66, while permitting fluorescent light 62 to pass therethrough to reach fluorescence detectors 30. Preferably beam splitter 84 is configured to only partially reflect light portions 69, to coordinate its efficiency with beam splitter 70, and includes a chromatic filter element (not shown) which passes through fluorescent emission 62, typically in the yellow spectrum, and which filters out substantially all reflected portions 69, typically in the blue spectrum, which would otherwise pass through to detectors 30.

It is appreciated by persons skilled in the art that the present invention is not limited by what has been particularly shown and described hereinabove. Rather the present invention includes modifications and variations thereof which would occur to a person of skill in the art upon reading the foregoing description and which are not in the prior art.

1. An inspection system for electrical circuits comprising:
a conveying subsystem for conveying an electrical circuit to be inspected in at least one direction;
an inspection subsystem for performing optical inspection of said electrical circuit as it is being conveyed in said at least one direction, said inspection subsystem comprising:
a laser beam generator generating a laser beam;
a laser beam scanner operative to scan said laser beam in at least one second direction which is at least generally perpendicular to said first direction; and
at least one fluorescence detector for detecting fluorescence produced by impingement of said laser beam on portions of said electrical circuit, said at least one fluorescence detector receiving fluorescence sequentially from portions of said electrical circuit illuminated by said laser beam as a result of both conveying of said electrical circuit in said at least one direction and scanning of said laser beam in said at least one second direction.

2. An inspection system according to claim 1 and wherein said laser beam scanner comprises an f-θ optical element.

3. An inspection system according to claim 2 and wherein said f-θ optical element comprises a lens.

4. An inspection system according to claim 2 and wherein said f-θ optical element comprises a mirror.

5. An inspection system according to claim 2 and wherein said f-θ optical element comprises parabolic and hyperbolic optical surfaces.

6. An inspection system according to claim 1 and wherein said laser beam generator comprises a diode laser.

7. An inspection system according to claim 6 and where said diode laser is a gallium nitride laser.

8. An inspection system according to claim 1 and wherein said laser beam generator comprises an optically pumped semiconductor laser.

9. An inspection system according to claim 1 and wherein said laser beam generator comprises a gas laser.

10. An inspection system according to claim 9 and where said diode laser is a cadmium:helium laser.

11. An inspection system according to claim 1 and also comprising a reflectance detector.

12. An inspection system according to claim 11 and wherein said reflectance detector comprises a light guide.

13. An inspection system according to claim 1 and wherein said at least one fluorescence detector comprises a light guide and a photomultiplier tube.

14. An inspection system according to claim 1 and wherein said at least one fluorescence detector comprises a plurality of fluorescence detectors.

15. An inspection system for electrical circuits comprising: a conveying subsystem for conveying an electrical circuit to be
inspected in at least one direction;
an inspection subsystem for performing optical inspection of said electrical circuit as it is being conveyed in said at least one direction, said inspection subsystem comprising:
a laser beam generator generating a laser beam;
a laser beam scanner operative to scan said laser beam in a single pass across said entire electrical circuit in at least one second direction which is at least generally perpendicular to said first direction;
a fluorescence detector for detecting fluorescence produced by impingement of said laser beam on portions of said electrical circuit.

16. An inspection system according to claim 15 and wherein said fluorescence detector receiving fluorescence sequentially from portions of said electrical circuit illuminated by said laser beam as a result of both conveying of said electrical circuit in said at least one direction and scanning of said laser beam in said at least one second direction.

17. An inspection system according to claim 15 and wherein said laser beam scanner comprises an f-θ optical element.

18. An inspection system according to claim 17 and wherein said f-θ optical element comprises a lens.

19. An inspection system according to claim 17 and wherein said f-θ optical element comprises a mirror.

20. An inspection system according to claim 17 and wherein said f-θ optical element comprises parabolic and hyperbolic optical surfaces.

21. An inspection system according to claim 15 and wherein said laser beam generator comprises a diode laser.

22. An inspection system according to claim 21 and where said diode laser is a gallium nitride laser.

23. An inspection system according to claim 15 and wherein said laser beam generator comprises an optically pumped semiconductor laser.

24. An inspection system according to claim 15 and wherein said laser beam generator comprises a gas laser.

25. An inspection system according to claim 24 and where said diode laser is a cadmium:helium laser.

26. An inspection system according to claim 16 and also comprising a reflectance detector.

27. An inspection system according to claim 26 and wherein said reflectance detector comprises a light guide.

28. An inspection system according to claim 15 and wherein said at least one fluorescence detector comprises a light guide and a photomultiplier tube.

29. An inspection system according to claim 15 and wherein said at least one fluorescence detector comprises a plurality of fluorescence detectors.

30. An inspection system for electrical circuits comprising:
a conveying subsystem for conveying an electrical circuit to be inspected in at least one direction;
an inspection subsystem for performing optical inspection of said electrical circuit, said inspection subsystem comprising:
a laser beam generator generating a laser beam;
a laser beam scanner operative to scan said laser beam in at least one second direction which is at least generally perpendicular to said first direction, said laser beam scanner including a rotating polygon mirror and a laser beam deflector, receiving said laser beam from said laser beam scanner and deflecting said laser beam onto said electrical circuit as a function of the rotational position of the rotating polygon mirror; and
a fluorescence detector for detecting fluorescence produced by impingement of said laser beam on portions of said electrical circuit.

31. An inspection system according to claim 30 and wherein said fluorescence detector receiving fluorescence sequentially from portions of said electrical circuit illuminated by said laser beam as a result of both conveying of said electrical circuit in said at least one direction and scanning of said laser beam in said at least one second direction.

32. An inspection system according to claim 30 and wherein said laser beam scanner comprises an f-θ optical element.

33. An inspection system according to claim 31 and wherein said f-θ optical element comprises a lens.

34. An inspection system according to claim 31 and wherein said f-θ optical element comprises a mirror.

35. An inspection system according to claim 32 and wherein said f-θ optical element comprises parabolic and hyperbolic optical surfaces

36. An inspection system according to claim 30 and wherein said laser beam generator comprises a diode laser.

37. An inspection system according to claim 36 and where said diode laser is a gallium nitride laser.

38. An inspection system according to claim 30 and wherein said laser beam generator comprises an optically pumped semiconductor laser.

39. An inspection system according to claim 30 and wherein said laser beam generator comprises a gas laser.

40. An inspection system according to claim 39 and where said diode laser is a cadmium:helium laser.

41. An inspection system according to claim 31 and also comprising a reflectance detector.

42. An inspection system according to claim 41 and wherein said reflectance detector comprises a light guide.

43. An inspection system according to claim 30 and wherein said inspection subsystem performs optical inspection of said electrical circuit as it is being conveyed in said at least one direction.

44. An inspection system according to claim 30 and wherein said at least one fluorescence detector comprises a light guide and a photomultiplier tube.

45. An inspection system according to claim 30 and wherein said at least one fluorescence detector comprises a plurality of fluorescence detectors.

46. An inspection system for electrical circuits comprising:
a conveying subsystem for conveying an electrical circuit to be inspected in at least one direction, said electrical circuit including a non-metallic substrate;
an inspection subsystem for performing optical inspection of said electrical circuit, said inspection subsystem comprising:
a laser beam generator chosen from the group consisting of diode lasers and frequency transformed optically pumped semiconductor lasers;
a laser beam scanner operative to scan said laser beam in at least one second direction which is at least generally perpendicular to said first direction; and
a fluorescence detector for detecting fluorescence produced by impingement of said laser beam on portions of said electrical circuit.

47. An inspection system according to claim 46 and also comprising a reflectance detector.

48. An inspection system according to claim 47 and wherein said laser beam scanner comprises a rotating polygon mirror and a laser beam deflector, receiving said laser beam from said laser beam scanner and deflecting said laser beam onto said electrical circuit, as a function of the rotational position of the rotating polygon mirror.

49. A method for inspecting electrical circuits comprising:
providing a plurality of scanning laser inspection means wherein at least two of said scanning laser inspection means employ laser beam generating means each emitting a laser beam having a different spectral characteristic; and
supplying an electrical circuit to be inspected to one of said scanning laser inspection means as a function of a fluorescent response resulting from an interaction between a substrate portion of said electrical circuit to be inspected and the laser beam employed in said scanning laser inspection means and impinging thereon.

50. A method for inspecting electrical circuits comprising:
providing scanning laser inspection means comprising at least two laser beam generating means each emitting a laser beam having a different spectral characteristic; and
selecting one of said laser beam generating means for use in inspecting an electrical circuit to be inspected said laser beam generating means being selected as a function of a fluorescent response resulting from an interaction between a substrate portion of said electrical circuit and a laser beam emitted by said at least two laser beam generating means when impinging on said electrical circuit.

51. A method for inspecting electrical circuits according to claim 50 and wherein said scanning laser inspection means comprises at least two laser beam generating means mounted therein, and said selecting includes switching between one of two laser beam generating means.

52. A method for inspecting electrical circuits according to claim 50 and wherein said selecting comprises removing a first laser beam generating means from said inspection means, and installing a second laser beam generating means.
